(19) United States
(12) Patent Application Publication
(10) Pub. No.: US 2013/0113089 A1
(43) Pub. Date: May 9, 2013

(54) MODULE IC PACKAGE STRUCTURE HAVING A METAL SHIELDING FUNCTION FOR PREVENTING ELECTRICAL MALFUNCTION INDUCED BY SHORT-CIRCUIT

(71) Applicants: CHUNG-ER HUANG, NEW TAIPEI CITY (TW); YUEH-CHENG LEE, NEW TAIPEI CITY (TW)

(72) Inventors: CHUNG-ER HUANG, NEW TAIPEI CITY (TW); YUEH-CHENG LEE, NEW TAIPEI CITY (TW)

(73) Assignee: AZUREWAVE TECHNOLOGIES, INC., NEW TAIPEI CITY (TW)

(21) Appl. No.: 13/326,478

(22) Filed: Dec. 15, 2011

(30) Foreign Application Priority Data
Nov. 9, 2011 (TW) 100221163

(51) Int. Cl. H01L 23/552

(52) U.S. Cl. 257/660; 257/E23.114

(57) ABSTRACT

A module IC package structure having a metal shielding function includes a substrate unit, an electronic unit, a shielding unit, and an insulative unit. The substrate unit includes a substrate body and at least one grounding pad disposed on the substrate body. The electronic unit includes at least one electronic module disposed on the circuit substrate and electrically connected to the circuit substrate. The shielding unit includes a metal shielding layer formed on an external surface of the at least one electronic module, and the metal shielding layer contacts the at least one grounding pad. The insulative unit includes an insulative layer formed on an external surface of the metal shielding layer. Hence, the module IC package structure can be used to prevent electrical malfunction induced by short-circuit due to the design of forming the insulative layer formed on the external surface of the metal shielding layer.

### BACKGROUND OF THE INVENTION

1. Field of the Invention

The instant disclosure relates to a module IC package structure, and more particularly, to a module IC package structure having a metal shielding function for preventing electrical malfunction induced by short-circuit.

2. Description of Related Art

As integrated circuit technology has been rapidly developing, a variety of devices using the technology are developed continuously. Because the functions of the devices are rapidly added, most devices are implemented in a modular way. However, while the functions of the devices can be increased by integrating a lot of functional modules, the design of a multiple function device with small dimensions is still difficult.

In the semiconductor manufacturing process, a high level technology is used to manufacture a small chip or component. Therefore, the module manufacturer can design a functional module with small dimensions, and the device can be efficiently and fully developed. Currently, most modules use the printed circuit board (PCB), Flame Retardant 4 (FR-4), or Bismaleimide Triazine (BT) substrate as a carrier. All chips and components are mounted onto the surface of the carrier by using a surface mounting technology (SMT). Therefore, the substrate is merely used as a carrier and is used for connecting the circuit. The structure of the substrate is a multiple-layered structure and is only used for the circuit layout.

Following the development of radio frequency technology, wireless communication systems are becoming more powerful and their performance increases. Demands on these systems are low weight, small dimensions, high quality, low energy-consumption high reliability, and low manufacturing costs. Another important function of wireless communication systems is the electric shielding of radiation emitted by their components in order to minimize interference of this radiation with other electronic devices or components.

In many cases the shielding structure is realized as a sheet steel casing around the wireless device or circuit module, necessitating the manufacture of costly dies for each shielding structure shape.

### SUMMARY OF THE INVENTION

One aspect of the instant disclosure relates to a module IC package structure having a metal shielding function for preventing electrical malfunction induced by short-circuit.

One of the embodiments of the instant disclosure provides a module IC package structure having a metal shielding function for preventing electrical malfunction induced by short-circuit, comprising: a substrate unit, an electronic unit, a shielding unit, and an insulative unit. The substrate unit includes a substrate body and at least one grounding pad disposed on the substrate body. The electronic unit includes at least one electronic module disposed on the circuit substrate and electrically connected to the circuit substrate. The shielding unit includes a metal shielding layer formed on an external surface of the at least one electronic module, wherein the metal shielding layer contacts the at least one grounding pad. The insulative unit includes an insulative layer formed on an external surface of the metal shielding layer.

Another one of the embodiments of the instant disclosure provides a module IC package structure having a metal shielding function for preventing electrical malfunction induced by short-circuit, comprising: a substrate unit, an electronic unit, a shielding unit, and an insulative unit. The substrate unit includes a substrate body and at least one grounding pad disposed on the substrate body. The electronic unit includes at least one electronic module disposed on the circuit substrate and electrically connected to the circuit substrate. The shielding unit includes a metal shielding layer disposed on the circuit substrate to enclose an external surface of the at least one electronic module, wherein the metal shielding layer contacts the at least one grounding pad. The insulative unit includes an insulative layer disposed on the circuit substrate to enclose an external surface of the metal shielding layer.

Yet another one of the embodiments of the instant disclosure provides a module IC package structure having a metal shielding function for preventing electrical malfunction induced by short-circuit, comprising: a substrate unit, an electronic unit, a package unit, a shielding unit, and an insulative unit. The substrate unit includes a substrate body, at least one grounding pad disposed on the substrate body, and at least one solder disposed on the substrate body. The electronic unit includes a plurality of electronic modules disposed on the circuit substrate and electrically connected to the circuit substrate. The package unit includes a package resin body formed on the substrate body to cover the electronic modules. The shielding unit includes a metal shielding layer disposed on the package resin body to enclose the package resin body, wherein the metal shielding layer contacts the at least one grounding pad. The insulative unit includes an insulative layer disposed on the metal shielding layer to insulate the metal shielding layer from the at least one solder.

Therefore, the module IC package structure of the instant disclosure can be used to prevent electrical malfunction induced by short-circuit due to the design of forming the insulative layer formed on the external surface of the metal shielding layer, placing the insulative layer on the circuit substrate to enclose the external surface of the metal shielding layer, or forming or placing the insulative layer on the metal shielding layer to insulate the metal shielding layer from the solder.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, schematic view of the module IC package structure according to the first embodiment of the instant disclosure;

FIG. 2 shows a lateral, schematic view of the module IC package structure according to the second embodiment of the instant disclosure;

FIG. 3A shows a lateral, exploded, schematic view of the module IC package structure according to the third embodiment of the instant disclosure;

FIG. 3B shows a lateral, assembled, schematic view of the module IC package structure according to the third embodiment of the instant disclosure;

FIG. 4A shows a lateral, exploded, schematic view of the module IC package structure according to the fourth embodiment of the instant disclosure;

FIG. 4B shows a lateral, assembled, schematic view of the module IC package structure according to the fourth embodiment of the instant disclosure;

FIG. 5 shows a lateral, schematic view of the module IC package structure according to the fifth embodiment of the instant disclosure; and

FIG. 6 shows a lateral, schematic view of the module IC package structure according to the sixth embodiment of the instant disclosure.

### DETAILED DESCRIPTION OF THE PREFERRED EMBODIMENTS

### First Embodiment

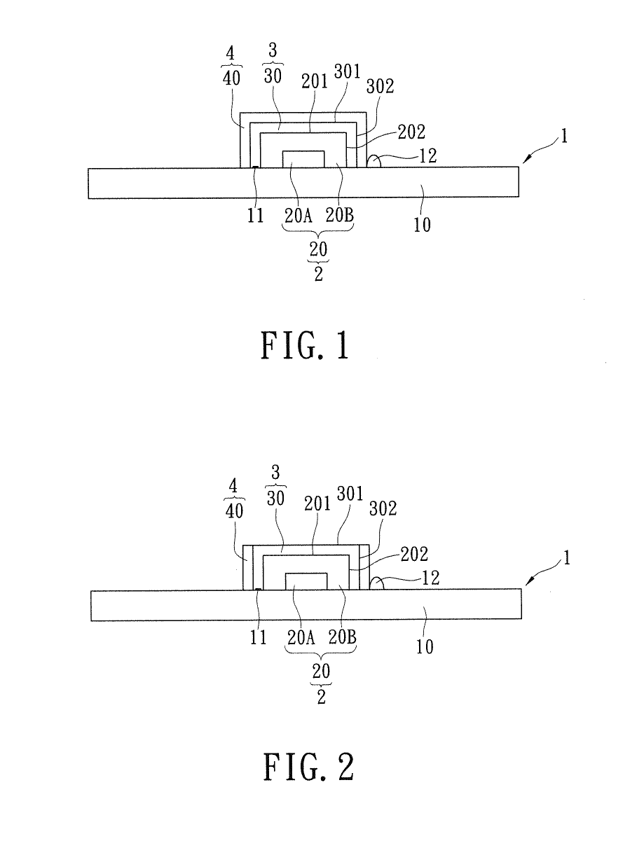

Referring to FIG. 1, where the first embodiment of the instant disclosure provides a module IC package structure having a metal shielding function for preventing electrical malfunction induced by short-circuit, comprising: a substrate unit 1, an electronic unit 2, a shielding unit 3, and an insulative unit 4.

The substrate unit 1 includes a substrate body 10, at least one grounding pad 11 disposed on the substrate body 10, and at least one solder 12 disposed on the substrate body 10. For example, the substrate body 10 may be a circuit substrate, the grounding pad 11 can be disposed on the top surface of the substrate body 10, and the solder 12 can be an electrical connection object for electrically connecting any electronic component with the substrate body 10. However, the at least one grounding pad 11 and the at least one solder 12 used in the first embodiment are merely an example and are not meant to limit the instant disclosure.

The electronic unit 2 includes at least one electronic module 20 disposed on the circuit substrate 10 and electrically connected to the circuit substrate 10. The electronic module 20 includes at least one electronic element 20A disposed on the substrate body 10 and electrically connected to the substrate body 10 and a package layer 20B disposed on the substrate body 10 to cover the electronic element 20A. For example, the electronic element 20A may be a resistance, a capacitance, an inductance, a function chip having a predetermined function, or a semiconductor chip having a predetermined function etc. However, the electronic element 20A used in the first embodiment is merely an example and is not meant to limit the instant disclosure.

The shielding unit 3 includes a metal shielding layer 30 formed on an external surface of the electronic module 20. The metal shielding layer 30 can contact the grounding pad 11, thus the metal shielding layer 30 can generate a metal shielding function for shielding the electronic module 20. For example, the metal shielding layer 30 can be formed on a top surface 201 and a peripheral surface 202 of the electronic module 20 for enclosing the electronic module 20. Hence, the electronic element 20A of the electronic module 20 can be shielded by the metal shielding layer 30. In addition, the metal shielding layer 30 may be formed by spraying to from a conductive spray layer, by sputtering to form a conductive sputtering layer, by printing to form a conductive printing layer, or by electroplating to form a conductive electroplating layer etc, according to different requirements. However, the metal shielding layer 30 used in the first embodiment is merely an example and is not meant to limit the instant disclosure.

The insulative unit 4 includes an insulative layer 40 formed on an external surface of the metal shielding layer 30. For example, the insulative layer 40 can be formed on a top surface 301 and a peripheral surface 302 of the metal shielding layer 30 for fully enclosing the metal shielding layer 30. In other words, the metal shielding layer 30 is insulated from the solder 12 by the insulative layer 40 between the metal shielding layer 30 and the solder 12, thus the solder 12 on the substrate body 10 cannot contact the metal shielding layer 30 through the insulative layer 40. Hence, the module IC package structure of the first embodiment can prevent electrical malfunction induced by short-circuit due to the metal shielding layer 30 absolutely insulated from the solder 12 by the insulative layer 40. In addition, the insulative layer 40 may be formed by spraying to from an insulative spray layer, by sputtering to form an insulative sputtering layer, by printing to form an insulative printing layer, or by PECVD to form an insulative deposition layer etc, according to different requirements. However, the insulative layer 40 used in the first embodiment is merely an example and is not meant to limit the instant disclosure.

### Second Embodiment

Referring to FIG. 2, where the second embodiment of the instant disclosure provides a module IC package structure having a metal shielding function for preventing electrical malfunction induced by short-circuit, comprising: a substrate unit 1, an electronic unit 2, a shielding unit 3, and an insulative unit 4.

Comparing FIG. 2 with FIG. 1, the difference between the second embodiment and the first embodiment is as follows: in the second embodiment, the insulative layer 40 is only formed on a peripheral surface 302 of the metal shielding layer 30 for only exposing a top surface 301 of the metal shielding layer 30. Although the insulative layer 40 is only formed on the peripheral surface 302 of the metal shielding layer 30, the module IC package structure of the second embodiment also can prevent electrical malfunction induced by short-circuit due to the metal shielding layer 30 absolutely insulated from the solder 12 by the insulative layer 40.

### Third Embodiment

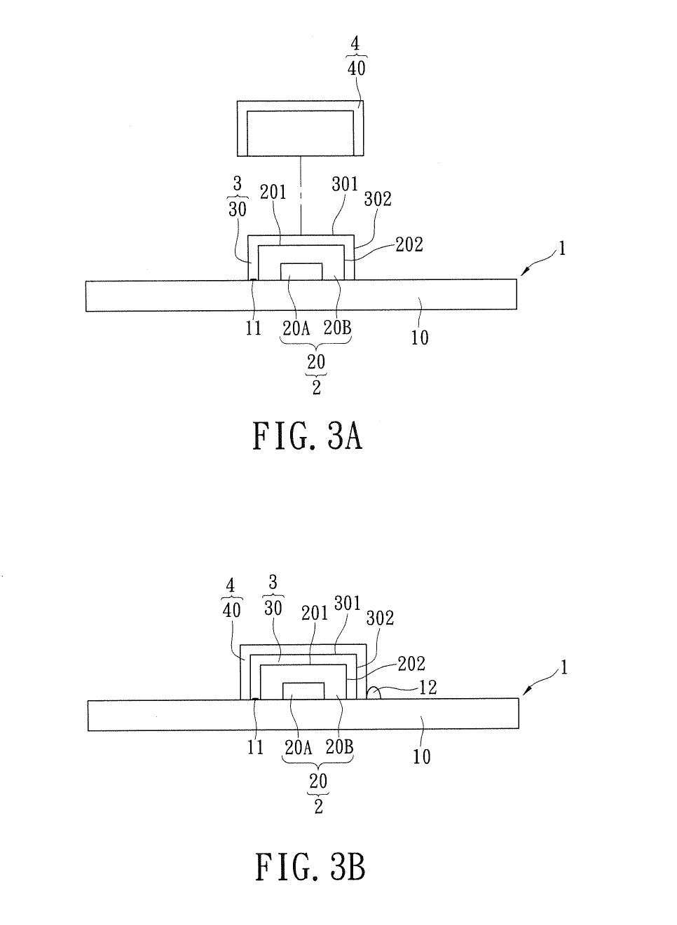

Referring to FIG. 3A and FIG. 3B, where the third embodiment of the instant disclosure provides a module IC package structure having a metal shielding function for preventing electrical malfunction induced by short-circuit, comprising: a substrate unit 1, an electronic unit 2, a shielding unit 3, and an insulative unit 4.

Comparing FIG. 3A with FIG. 1, the difference between the third embodiment and the first embodiment is as follows: in the third embodiment, the shielding unit 3 includes a metal shielding layer 30 disposed on the circuit substrate 10 to enclose an external surface of the electronic module 20, and the metal shielding layer 30 can be formed on a top surface 201 and a peripheral surface 202 of the electronic module 20 for enclosing the electronic module 20. The insulative unit 4 includes an insulative layer 40 disposed on the circuit substrate 10 to enclose an external surface of the metal shielding layer 40, and the insulative layer 40 can be formed on a top surface 301 and a peripheral surface 302 of the metal shielding layer 30 for enclosing the metal shielding layer 30. For example, the insulative layer 40 may be a prefabricated insulation cap, thus when the prefabricated insulation cap (the insulative layer 40) is disposed on the substrate body 10 to cover the top surface 301 and the peripheral surface 302 of the metal shielding layer 30, the module IC package structure of the third embodiment also can prevent electrical malfunction induced by short-circuit due to the metal shielding layer 30 absolutely insulated from the solder 12 by the insulative layer 40.

### Fourth Embodiment

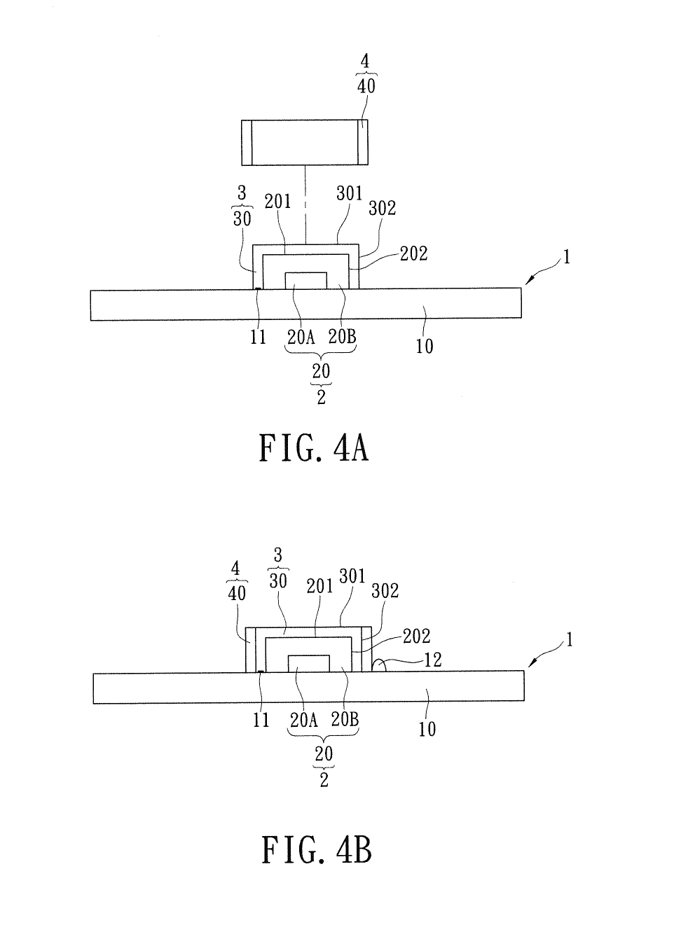

Referring to FIG. 4A and FIG. 4B, where the fourth embodiment of the instant disclosure provides a module IC package structure having a metal shielding function for preventing electrical malfunction induced by short-circuit, comprising: a substrate unit 1, an electronic unit 2, a shielding unit 3, and an insulative unit 4.

Comparing FIG. 4A with FIG. 3A and comparing FIG. 4B with FIG. 3B, the difference between the fourth embodiment and the third embodiment is as follows: in the fourth embodiment, the insulative layer 40 is only formed on a peripheral surface 302 of the metal shielding layer 30 for only exposing a top surface 301 of the metal shielding layer 30. For example, the insulative layer 40 may be a prefabricated surrounding body, thus the prefabricated surrounding body (the insulative layer 40) can be disposed on the substrate body 10 to only cover the peripheral surface 302 of the metal shielding layer 30. Although the insulative layer 40 is only formed on the peripheral surface 302 of the metal shielding layer 30, the module IC package structure of the fourth embodiment also can prevent electrical malfunction induced by short-circuit due to the metal shielding layer 30 absolutely insulated from the solder 12 by the insulative layer 40.

### Fifth Embodiment

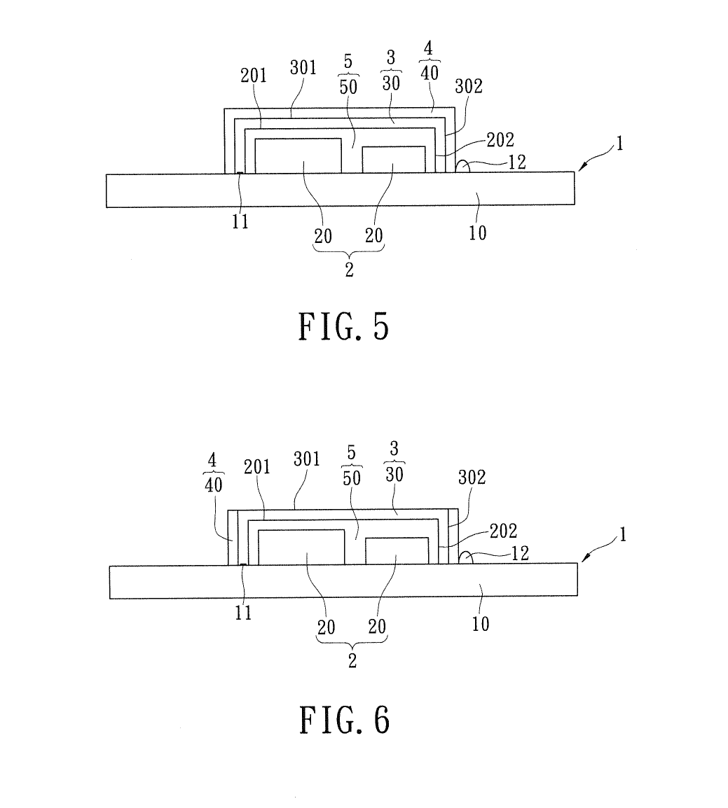

Referring to FIG. 5, where the fifth embodiment of the instant disclosure provides a module IC package structure having a metal shielding function for preventing electrical malfunction induced by short-circuit, comprising: a substrate unit 1, an electronic unit 2, a package unit 5, a shielding unit 3, and an insulative unit 4.

The substrate unit 1 includes a substrate body 10, at least one grounding pad 11 disposed on the substrate body 10, and at least one solder 12 disposed on the substrate body 10. The electronic unit 2 includes a plurality of electronic modules 20 disposed on the circuit substrate 10 and electrically connected to the circuit substrate 10. The package unit 5 includes a package resin body 50 formed on the substrate body 10 to cover the electronic modules 20. The shielding unit 3 includes a metal shielding layer 30 disposed on the package resin body 50 to enclose the package resin body 50. The metal shielding layer 30 can contact the grounding pad 11, thus the metal shielding layer 30 can generate a metal shielding function for shielding the electronic module 20.

Moreover, the insulative unit 4 includes an insulative layer 40 disposed on the metal shielding layer 30 to insulate the metal shielding layer 30 from the solder 12. In other words, the metal shielding layer 30 is insulated from the solder 12 by the insulative layer 40 between the metal shielding layer 30 and the solder 12, thus the solder 12 on the substrate body 10 cannot contact the metal shielding layer 30 through the insulative layer 40. Hence, the module IC package structure of the fifth embodiment can prevent electrical malfunction induced by short-circuit due to the metal shielding layer 30 absolutely insulated from the solder 12 by the insulative layer 40.

### Sixth Embodiment

Referring to FIG. 6, where the sixth embodiment of the instant disclosure provides a module IC package structure having a metal shielding function for preventing electrical malfunction induced by short-circuit, comprising: a substrate unit 1, an electronic unit 2, a package unit 5, a shielding unit 3, and an insulative unit 4.

Comparing FIG. 6 with FIG. 5, the difference between the sixth embodiment and the fifth embodiment is as follows: in the sixth embodiment, the insulative layer 40 is only formed on a peripheral surface 302 of the metal shielding layer 30 for only exposing a top surface 301 of the metal shielding layer 30. Although the insulative layer 40 is only formed on the peripheral surface 302 of the metal shielding layer 30, the module IC package structure of the sixth embodiment also can prevent electrical malfunction induced by short-circuit due to the metal shielding layer 30 absolutely insulated from the solder 12 by the insulative layer 40.

Therefore, the module IC package structure of the instant disclosure can be used to prevent electrical malfunction induced by short-circuit due to the design of forming the insulative layer formed on the external surface of the metal shielding layer, placing the insulative layer on the circuit substrate to enclose the external surface of the metal shielding layer, or forming or placing the insulative layer on the metal shielding layer to insulate the metal shielding layer from the solder.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A module IC package structure having a metal shielding function for preventing electrical malfunction induced by short-circuit, comprising:
a substrate unit including a substrate body and at least one grounding pad disposed on the substrate body;
an electronic unit including at least one electronic module disposed on the circuit substrate and electrically connected to the circuit substrate;
a shielding unit including a metal shielding layer formed on an external surface of the at least one electronic module, wherein the metal shielding layer contacts the at least one grounding pad; and
an insulative unit including an insulative layer formed on an external surface of the metal shielding layer.

2. The module IC package structure of claim 1, wherein the substrate unit includes at least one solder disposed on the substrate body for contacting the insulative layer and insulating from the metal shielding layer.

3. The module IC package structure of claim 1, wherein the at least one electronic module includes at least one electronic element disposed on the substrate body and electrically connected to the substrate body and a package layer disposed on the substrate body to cover the at least one electronic element.

4. The module IC package structure of claim 1, wherein the metal shielding layer is formed on a top surface and a peripheral surface of the at least one electronic module for enclosing the at least one electronic module.

5. The module IC package structure of claim 1, wherein the insulative layer is formed on a top surface and a peripheral surface of the metal shielding layer for enclosing the metal shielding layer.

6. The module IC package structure of claim 1, wherein the insulative layer is only formed on a peripheral surface of the metal shielding layer for only exposing a top surface of the metal shielding layer.

7. A module IC package structure having a metal shielding function for preventing electrical malfunction induced by short-circuit, comprising:
a substrate unit including a substrate body and at least one grounding pad disposed on the substrate body;
an electronic unit including at least one electronic module disposed on the circuit substrate and electrically connected to the circuit substrate;
a shielding unit including a metal shielding layer disposed on the circuit substrate to enclose an external surface of the at least one electronic module, wherein the metal shielding layer contacts the at least one grounding pad; and
an insulative unit including an insulative layer disposed on the circuit substrate to enclose an external surface of the metal shielding layer.

8. The module IC package structure of claim 7, wherein the substrate unit includes at least one solder disposed on the substrate body for contacting the insulative layer and insulating from the metal shielding layer.

9. The module IC package structure of claim 7, wherein the at least one electronic module includes at least one electronic element disposed on the substrate body and electrically connected to the substrate body and a package layer disposed on the substrate body to cover the at least one electronic element.

10. The module IC package structure of claim 7, wherein the metal shielding layer is formed on a top surface and a peripheral surface of the at least one electronic module for enclosing the at least one electronic module.

11. The module IC package structure of claim 7, wherein the insulative layer is formed on a top surface and a peripheral surface of the metal shielding layer for enclosing the metal shielding layer.

12. The module IC package structure of claim 7, wherein the insulative layer is only formed on a peripheral surface of the metal shielding layer for only exposing a top surface of the metal shielding layer.

13. A module IC package structure having a metal shielding function for preventing electrical malfunction induced by short-circuit, comprising:
a substrate unit including a substrate body, at least one grounding pad disposed on the substrate body, and at least one solder disposed on the substrate body;
an electronic unit including a plurality of electronic modules disposed on the circuit substrate and electrically connected to the circuit substrate;
a package unit including a package resin body formed on the substrate body to cover the electronic modules;
a shielding unit including a metal shielding layer disposed on the package resin body to enclose the package resin body, wherein the metal shielding layer contacts the at least one grounding pad; and
an insulative unit including an insulative layer disposed on the metal shielding layer to insulate the metal shielding layer from the at least one solder.
